(19) United States
(12) Patent Application Publication
(10) Pub. No.: US 2014/0052906 A1
(43) Pub. Date: Feb. 20, 2014

(54) MEMORY CONTROLLER RESPONSIVE TO LATENCY-SENSITIVE APPLICATIONS AND MIXED-GRANULARITY ACCESS REQUESTS

(71) Applicant: Rambus Inc., Sunnyvale, CA (US)

(72) Inventors: Vidhya Thyagarajan, Bangalore (IN); Prasanna Kole, Bangalore (IN); Dinesh Malviya, Bangalore (IN)

(73) Assignee: Rambus Inc., Sunnyvale, CA (US)

(21) Appl. No.: 13/959,500

(22) Filed: Aug. 5, 2013

Related U.S. Application Data
(60) Provisional application No. 61/684,395, filed on Aug. 17, 2012.

(51) Int. Cl. G11C 7/10; G06F 12/00

(52) U.S. Cl. CPC G11C 7/1072; G06F 12/00
USPC 711/105; 711/154

(57) ABSTRACT

A multi-channel memory controller (110, 600) may be dynamically re-architected to schedule low and high-latency memory access requests differently (FIG. 12) in order to make more efficient use of memory resources and improve overall performance. Data may be duplicated or “cloned” in a clone area (612) of one or more channels of a multi-channel or module threaded memory (610), the clone area being reserved by the memory controller. Cloning information is stored in a clone mapping table 620, preferably reflecting memory channel locations, including clone locations, per memory address range. An operating system may request a selected number of channels for cloning, see (622), based on application latency requirements or sensitivity, by storing the request in the clone mapping table. Coarse granularity access requests also may be dynamically scheduled across one or more first-available channels of the multi-channel or module threaded memory (1504) in a modified controller (1500).

### RELATED APPLICATIONS

This application is a non-provisional of, and claims priority to, U.S. Provisional Application No. 61/684,395 filed Aug. 17, 2012 all of which is incorporated herein in its entirety.

### COPYRIGHT NOTICE

©2013 RAMBUS INC. A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever. 37 CFR §1.71(d).

### BACKGROUND OF THE INVENTION

Memory controllers comprising circuits, software, or a combination of both, are used to service requests to access memory. Memory controllers may be standalone or integrated “on-chip,” for example in a microprocessor. Here we use “memory” in a broad sense to include, without limitation, one or more of various integrated circuits, components, modules, sub-systems, etc.

Generally the functionality of a DRAM (Dynamic Random Access Memory) memory controller is to accept read and write requests from a client to a given address in memory, translate the request to one or more commands to the memory system, issue those commands to the DRAM devices in the proper sequence and proper timing, and retrieve or store data on behalf of the client (e.g., a processor or I/O devices in the system).

Memory access operations necessarily incur some latency. For a read request, latency is the delay from the time of initiating the read operation to receipt of first data. Various agents or applications are more or less sensitive to latency. Even in multi-threaded or multi-channel memory systems, latency-sensitive applications may have to wait for a channel to become available. In addition, various requests may have differing granularity, also leading to performance challenges.

### BRIEF DESCRIPTION OF THE DRAWINGS

FIG. 1 is a simplified block diagram illustrating an example of an environment in which aspects of the present disclosure may be used to advantage.

FIG. 2 is a simplified timing diagram illustrating an example of write request scheduling in a memory system without data cloning.

FIG. 3 is a simplified timing diagram illustrating an example of write request scheduling in a memory system with data cloning.

FIG. 4 is a simplified timing diagram illustrating an example of read request scheduling without data cloning.

FIG. 5 is a simplified timing diagram illustrating an example of read request scheduling with data cloning.

FIG. 6 is a simplified functional block diagram illustrating selected aspects of a cloning memory controller coupled to a multi-channel memory.

FIGS. 7A-7B are simplified flow diagrams illustrating an example of processing a memory access request in a memory controller with data cloning.

FIG. 8 is a simplified block diagram illustrating various memory requests or tasks of both fine and coarse granularity presented to a multi-agent memory controller for accessing a multi-channel memory.

FIG. 9 is a simplified timing diagram illustrating an example of fine granularity requests evenly distributed to both threads of a two-threaded memory.

FIG. 10 is a simplified timing diagram illustrating an example of fine and coarse granularity requests unevenly distributed to two memory threads.

FIG. 11 is a simplified timing diagram illustrating an example of dynamic scheduling of different portions of a coarse granularity request simultaneously on two memory threads.

FIG. 12 is a simplified timing diagram illustrating an example of dynamic scheduling of different portions of a coarse granularity request using two respective requests on two memory threads.

FIG. 13 is a simplified timing diagram illustrating an example of fine and coarse granularity requests with dynamic scheduling on two memory threads.

FIG. 14 is a simplified block diagram illustrating one example of a memory controller architecture including logic to implement dynamic scheduling of memory access requests.

### DETAILED DESCRIPTION OF PREFERRED EMBODIMENTS

Several memory controller and memory access concepts, methods and apparatus are disclosed in which multi-channel memories can be utilized to improve performance, especially for latency-sensitive and or coarse or mixed-granularity access requests. We use the term “multi-channel” herein in a broad sense. For example, a threaded memory is a species of a multi-channel memory. In the discussion below, except as otherwise stated, “threaded memory” and “multi-channel memory” are used interchangeably. A coarse granularity request may be defined as one where the data size of the request is greater than the single-transaction data size of one memory channel or thread.

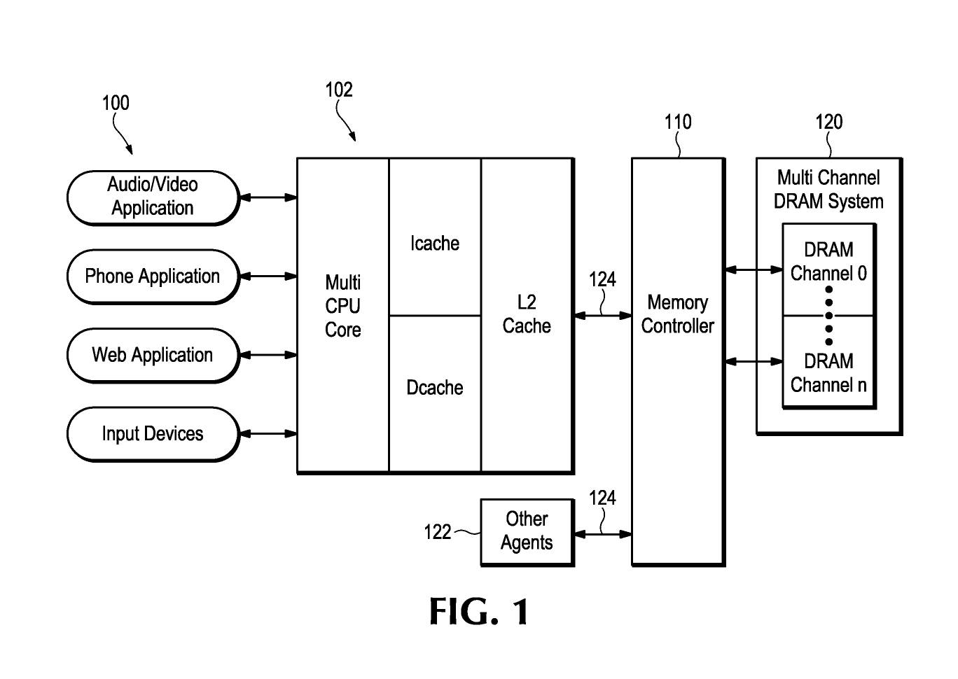

FIG. 1 is a simplified block diagram illustrating one example of an environment in which aspects of the present disclosure may be used to advantage. The drawing figure shows various application programs and/or devices 100, coupled to or executable on a processor 102, which in this example includes a multi-CPU core, instruction and data caches, and an L2 cache. The processor 102 may take various forms, e.g. an IC “chip” or chip set, SOC, circuit board, etc. It may be part of any digital device (e.g. computer, phone, PDA, laptop, pad computer, PC, etc.). The processor 102 is coupled to a memory controller 110, which in turn provides operational access to a memory 120. Other agents 122 may be coupled to the controller as well, to access the memory 120. In other words, in this illustration, the controller 110 has at least two user interfaces 124. The memory 120 may comprise a multi-channel DRAM system. The drawing shows DRAM channels numbered 0 to N (where N is a positive, non-zero integer).

Memory Write Access Requests

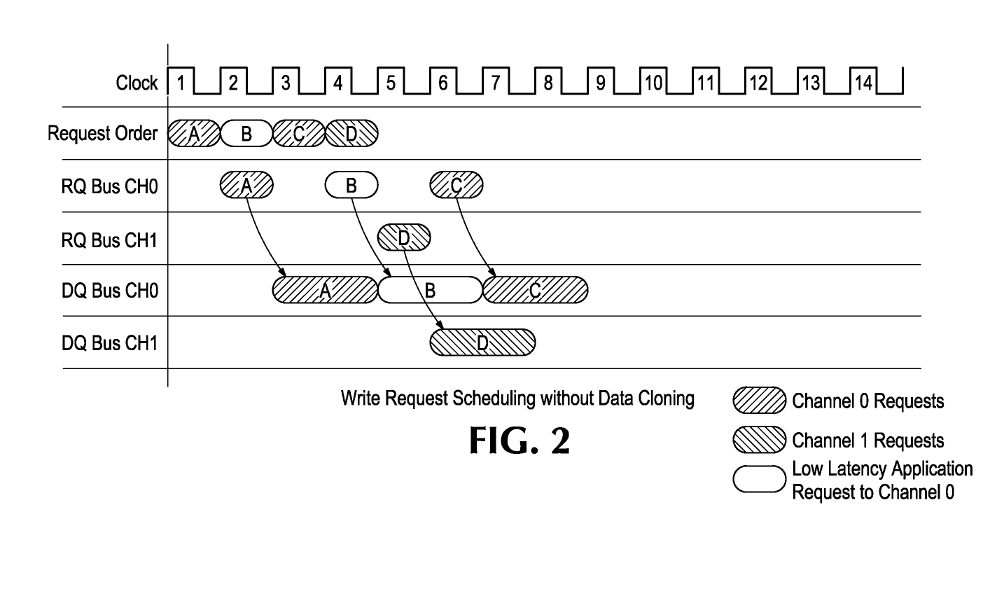

Write access requests may be presented to the controller user interface 124 by the processor 102 in support of various applications or other agents 100, 122. Turning now to FIG. 2, it shows a simplified timing diagram illustrating an example of write request scheduling in a memory system without data cloning. The scheduling is done by the controller 110. Here, the controller interface receives a series of four requests, labeled A, B, C and D, synchronized to the clock signal as shown. In this example, we assume the memory 120 has two channels, channel 0 and channel 1. As indicated, A and C are channel 0 requests; D is a channel 1 request, and B is a low latency application request to channel 0. By “low latency application” or similar terms, we mean an application, device or other agent that is sensitive to latency in memory access requests. “Latency” in this context generally means the delay from the time of a memory access request until the access operation is completed.

In FIG. 2, the reader can observe that request A is scheduled (see “RQ Bus CH0”), and then the access operation occurs—here write data is presented on the DQ Bus CH0, beginning one clock cycle after scheduling. Referring now to access request B, it is scheduled next on RQ Bus CH0, but the access operation has to wait long enough to allow the request A operation to complete on DQ Bus CH0 before the request B operation can place data on DQ Bus CH0. Similarly, request C must await completion of request B on CH0. One can also observe that request D was scheduled and proceeded on DQ Bus Ch-1 without delay as that channel was not busy when request D arrived at the controller. FIG. 2 thus illustrates how write transactions are typically scheduled in a system without cloning.

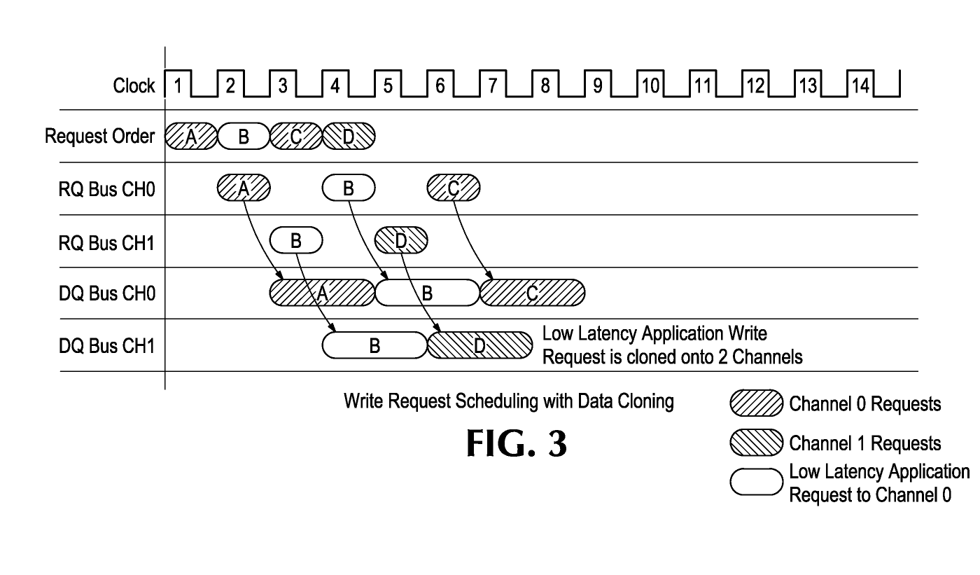

FIG. 3 is a simplified timing diagram illustrating an example of write request scheduling in a memory system with “data cloning” in accordance with the present disclosure. In FIG. 3, we see the same four write requests in the same order as in FIG. 2. Here, request A is scheduled and executed as before, on channel 0 (“DQ Bus CH0”). Request B, however, is scheduled or “cloned” to two channels (CH0 and CH1). That is because B has been identified as a write request associated with a low read latency application—an application that cannot tolerate long read latency, and is therefore supported in this example by cloning.

The timing diagram shows how the write request B begins execution first on channel 1 (DQ Bus CH1), as it is available. Channel 0 is busy servicing request A. After request A is completed, request B also proceeds on channel 0. Thus the request B can be allocated to more than one memory channel, and it can begin execution on the first available one of the allocated channels. The request B write data may be written to memory a first time on Channel 1, with a second copy or clone of the data written to memory on Channel 0. The same principles can be applied to schedule a request on more than two memory channels. Implementation of multi-channel cloning is described later. First we describe read request operations.

Memory Read Access Requests

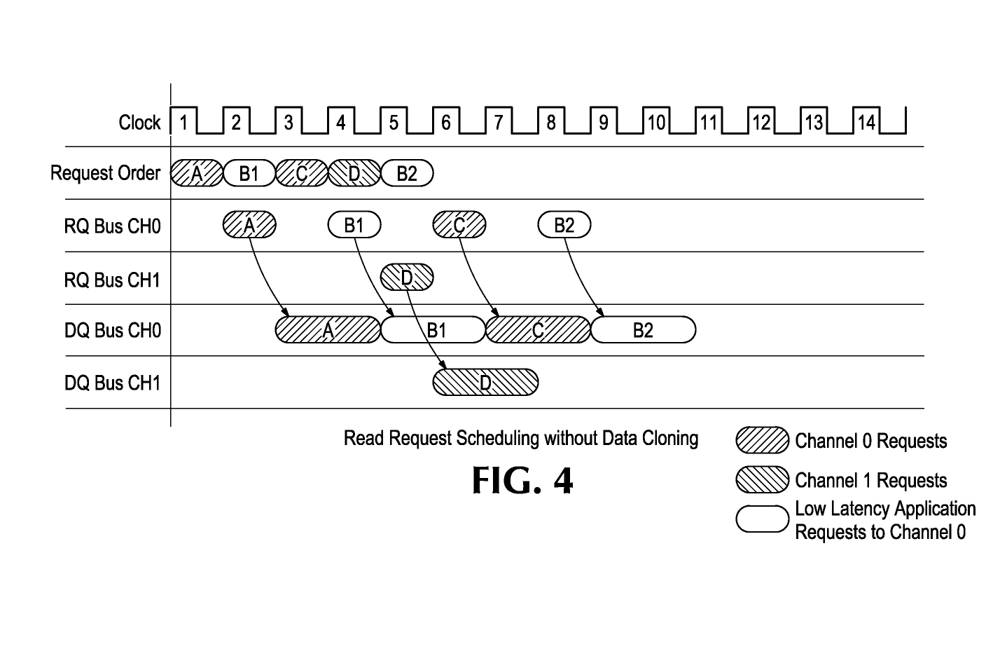

FIG. 4 is a simplified timing diagram illustrating an example of read request scheduling without data cloning. Although the figures, for simplification, do not illustrate latency between when a read request is received by a device and when the device places corresponding data on the data bus, typical devices are understood to have some inherent and/or programmable latency. In this figure, five access requests are shown, labeled A, B1, C, D, and B2 (a second request from application or agent B). As before, A and C are Channel 0 requests; D is a Channel 1 request; B1 and B2 are requests from a low-latency application B to Channel 0.

Here, request B1 is scheduled on Channel 0 (RQ Bus CH0), with data transfer queued until data transfer for the earlier request A has completed. Request C is scheduled next on Channel 0 and proceeds after B1 has completed. Finally, request B2 is scheduled on Channel 0, and like request B1, the request B2 data cannot be transferred before the request C data has completed data transfer on the DQ Bus CH0. Thus, in this example both client B access requests incur undesirable delay or latency because the requested channel (CH0) is busy at the earliest time when these requests could be scheduled. On the other hand, Channel 1 is not utilized at full bandwidth.

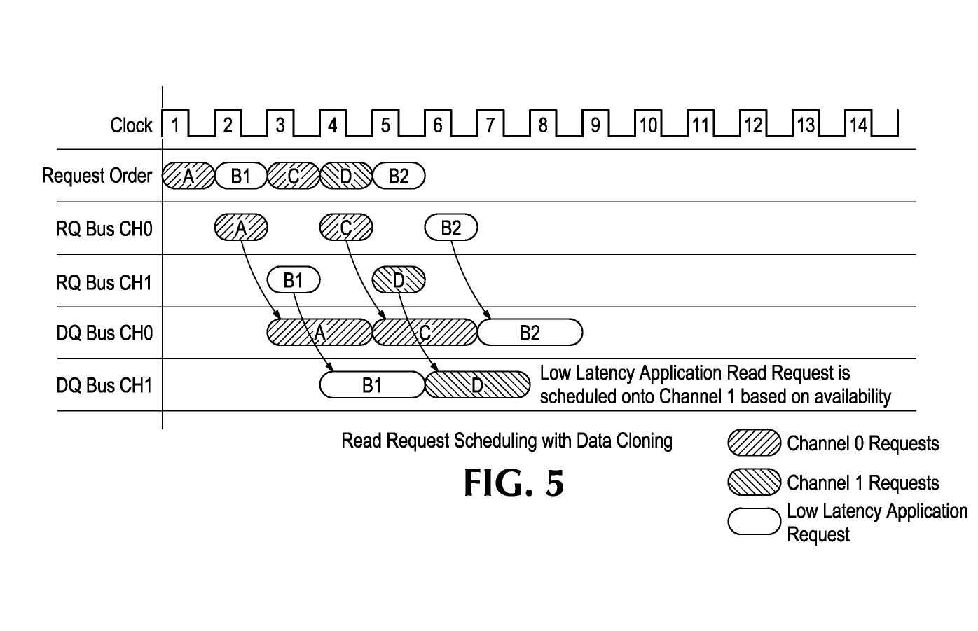

FIG. 5 is a simplified timing diagram illustrating an example of read request scheduling with data cloning. In FIG. 5, the same series of five access requests are presented as in FIG. 4. Here, however, the low-latency request B1 can be scheduled on the first available of Channels 0 and 1, as both channels contain copies of the data for the low-latency application. Even though Channel 0 is serving request A, request B1 does not have to wait for the request A on Channel 0, since the request B1 can be placed on Channel 1. Further, request B2 proceeds on Channel 0, again without significant delay, because Channel 0 is available whereas channel 1 is still busy servicing the request D. In a case where the requested read data is stored or “cloned” at two (or more) different channel locations in memory, the data transfer can begin on the first one of the channels that is available, so average latency is reduced. These operations are enabled by cloning selected data in the memory, e.g., as further explained below.

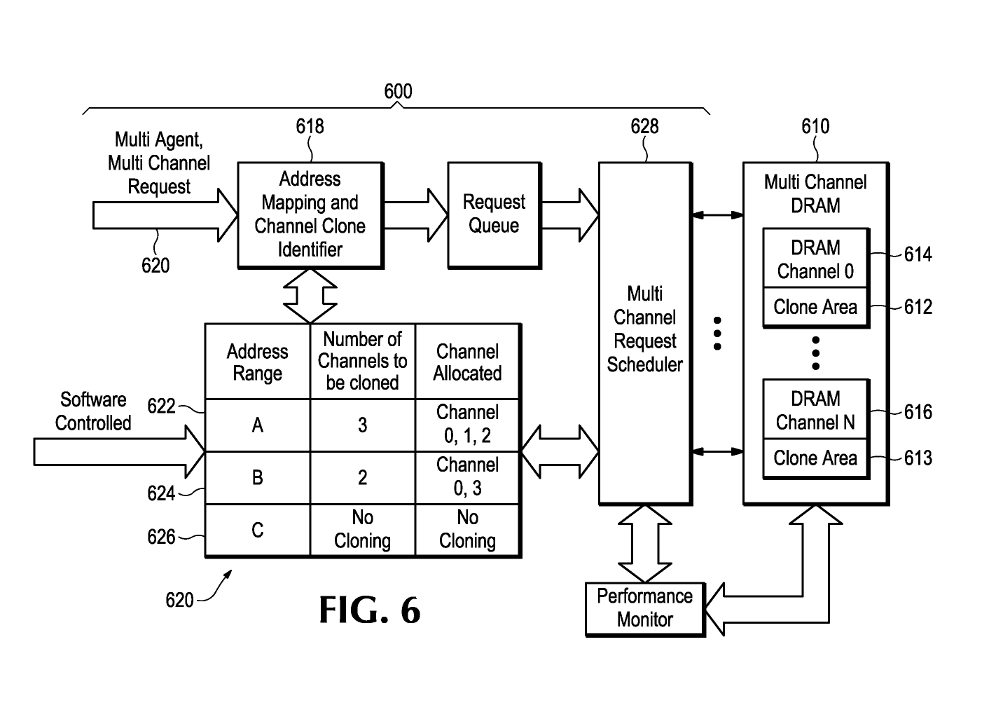

FIG. 6 is a simplified functional block diagram illustrating selected aspects of a cloning memory controller 600 coupled to a multi-channel memory 610. The controller 600 may reserve a portion, called a clone area 612, 613 in the DRAM connected to each channel 614, 616 of the memory 610. There may be more than two channels, as noted above, with two or more having clone areas. The controller 600 receives access requests from applications or other agents at interface 620. Data transfer to and from the applications or other agents (not shown) may be part of the same interface. The controller 600, upon receiving an access request, conducts address mapping, block 618, on the address associated with the request.

The controller also has logic (hardware and/or software) that accesses a stored clone mapping table 620 based on the mapped access request. The clone mapping table 620 stores cloning control information, preferably organized by memory address (or ranges of addresses). Cloning control information may be written to the mapping table by a host operating system or other user of a memory system. Additional information, such as identifiers of memory channels or threads where copies (clones) of data are stored in memory may be written into the mapping table by a controller as further described below.

In one example, the clone mapping table 620 includes a first row 622 for memory address range A, a second row 624 for address range B and a third row 626 for address range C. There may be additional address ranges, and the exact organization of the mapping table is not critical. In one embodiment, the clone mapping table is maintained in a register in a memory controller. The table may reside elsewhere on the same device, IC or SOC as the controller.

In some embodiments, an operating system (“OS”) configures the memory controller with at least some of the clone mapping data. Toward that end, the OS may identify at least one OS memory address range accessed by a latency-sensitive application. The OS determines a number of clones or copies to be created for that address range, to better support the latency-sensitive application, and the OS instructs the memory controller to configure that information in the mapping table. That OS memory address range of data will be identified within the memory controller with two or more address translation ranges existing respectively in different “clone areas” (612, 613) that exist behind at least two channels of the memory 610. A clone area is a region of memory, arranged such that one or more clone areas are associated with each channel or thread that is reserved by the controller logic for cloning.

For example, the OS may determine that a latency-sensitive application accesses OS address range B. The OS writes in row 624 of the clone mapping table 620 an indication, in the second column, that memory range B should be cloned to 2 channels. The number of channels to be cloned may be determined based on a response time requirement for the particular application or client. Channels 0 and 3 are allocated in the table for that purpose. Accordingly, the request scheduler 628 will generate commands to store address range B write data in the channel 0 clone area 612, (614 for channel 0), and also store the same data in the channel 1 clone area 613. In a preferred embodiment, the same physical device address range may be reserved for cloning on two DRAM ranks, such that a single address translation can be used to access either copy, by placing the physical address on either of the mapped channels.

Row 622 of the table illustrates assignment of three channels for cloning OS address range A, and no cloning (1 channel) for OS address range C. In another embodiment, there may be no entry in the table for an address range (say, C) for which no cloning is configured. When the table does not return a “hit” for that address range, the controller will default to the usual single address mapping.

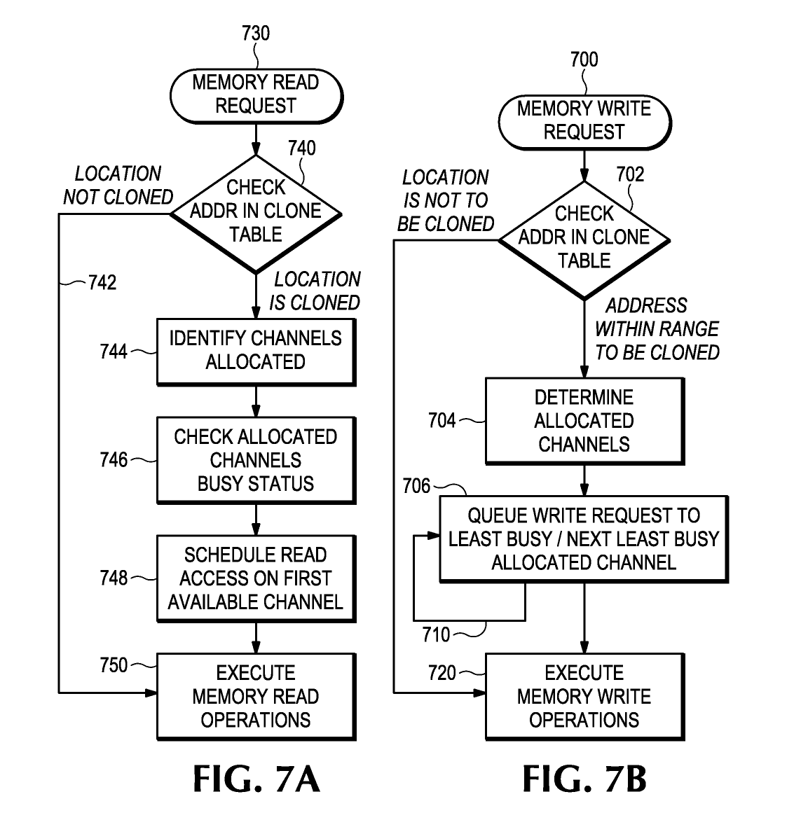

In operation, the controller will leverage the clone areas of memory to reduce latency, as follows. First, in the case of a memory write request, we refer to the simplified flow diagram of FIG. 7B. Responsive to a memory write request 700, the controller reads the clone mapping table, decision 702, based on an address range of the write request 700. Assume the address range is within range “B,” corresponding to row 624 of the mapping table in FIG. 6. The table entry calls for 2 channels as noted. Accordingly the logic flow takes the path labeled “address within range to be cloned” to step 704.

In step 704, the controller determines the allocated channels from the table entry. Then it queues a write request to the least busy of the allocated channels, say channel 0, in step 706. Next, because there is second channel allocated in this example, the logic loops at 710 and the controller queues another write request to the other allocated channel, channel 3, per the table 620 (FIG. 6). In general, the controller will queue a first write request to the least busy of the allocated channels, a second write request to the next least busy of the allocated channels, etc. The memory write requests are then executed, step 720.

The controller may store the write data into a number of channels of the memory that is fewer than the number of channels requested in the clone mapping table, depending on the clone space available. The controller need not report clone locations or the success or failure of clone requests to the host OS. Preferably, the address mapping and clone locations are transparent to the user.

FIG. 7A is a simplified flow diagram illustrating an example of processing a memory read request in a memory controller with data cloning. In the case of a read request 730, the controller logic again accesses the clone mapping table, decision 740, to look up the read request address range. If the address requested is not cloned, path 742, the controller proceeds to execute the requested read request in the usual fashion, step 750. If the requested address falls within an address range that is cloned, the method identifies, from the mapping table, the memory channels that were allocated to the read request address range, step 744. As noted above, these channel identifiers may be determined when the OS requests a cloned address space. Next, the process checks the status of the identified (allocated) channels, where the requested data may be found, step 746, to determine which channel(s) currently are busy and which are not busy, or alternately, if both (or all) are busy, the channel with the smaller current queue depth. Then, the read request is scheduled on the first available one of the allocated memory channels, step 748. Finally, the memory read operation(s) are executed, step 750.

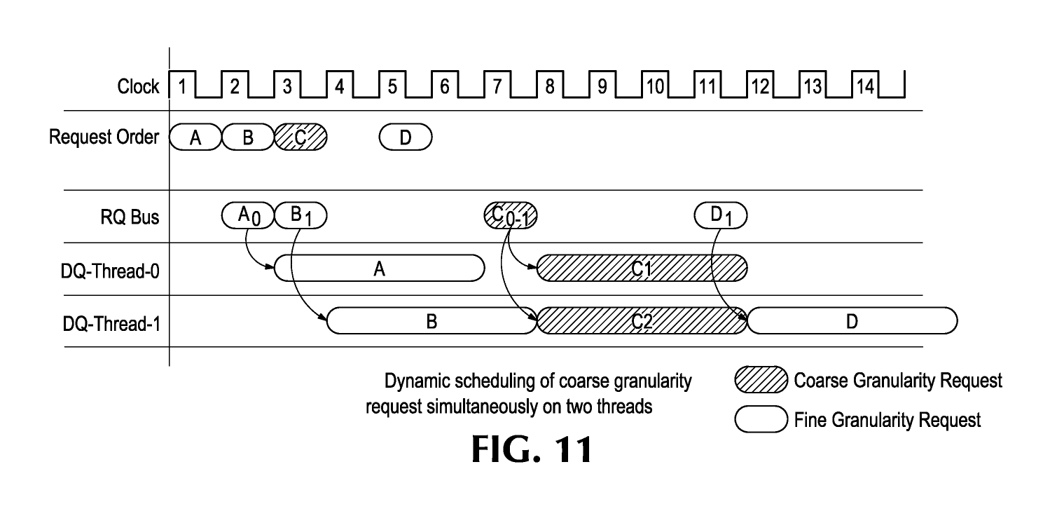

In some embodiments, where the requested read data is cloned, the memory access operations may comprise reading data from two or more of the designated channels of the memory concurrently to improve performance. Conversely, for a write request, where the data is to be cloned, the write access operations also may comprise writing duplicate data to the identified channels of the memory concurrently. Further, the memory access operations in a cloning context (read or write) may be executed substantially simultaneously or independently on multiple channels. In this way, performance improvements, especially reduced latency, may be realized in either or both of two ways—taking advantage of first-available among multiple channels, and/or taking advantage of accessing multiple channels in parallel. (See discussion below with regard to FIG. 11.)

In some embodiments, in a case where the corresponding entry in the clone mapping table identifies at least two memory channels for a given read request, the controller may split the read request by scheduling a respective portion of the read request on each of the allocated memory channels. This feature presumes the corresponding data was striped when written across the multiple different channels of the multi-channel memory.

Above, we described accessing a multiple-channel memory. The memory may have various arrangements and organization, not necessarily referred to as channels. For example, the memory may comprise a module threaded memory. The concepts described herein are fully applicable to such a memory. Each thread of the threaded memory may be considered analogous to a “channel” of a multi-channel memory. So, for example, the multi-threaded DRAM system 120 of FIG. 1 may instead comprise a module threaded memory. We use “module threaded” not to require a single module, but simply to distinguish from micro-threaded memory. A multi-channel or multi-threaded memory, as discussed above, may include micro-threaded memory devices internally, but that fact would not prevent application of the cloning concepts disclosed above, or other improvements described below.

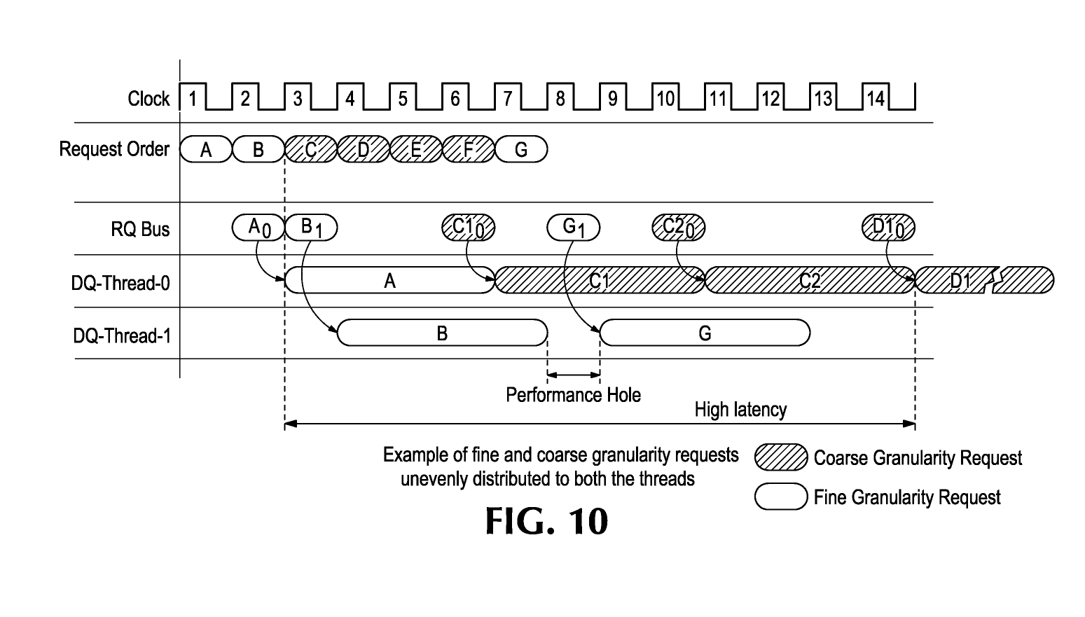

In a memory subsystem there may be multiple agents which present a mix of both fine and coarse granularity requests. Even a single agent can present a mix of fine and coarse granularity requests. A typical memory controller which supports module threading may be beneficial with regard to agents having only fine granularity requests; but agents may suffer increased latency and lower performance for coarse granularity requests. (This is illustrated in FIG. 10, described below.) Performance can be improved for mixed fine and coarse granularity applications by carefully scheduling requests on the fly to one or more channels or threads as explained below. Scheduling strategies may take into account, for example, size of access requests, bus width of the requesting agent, and other factors.

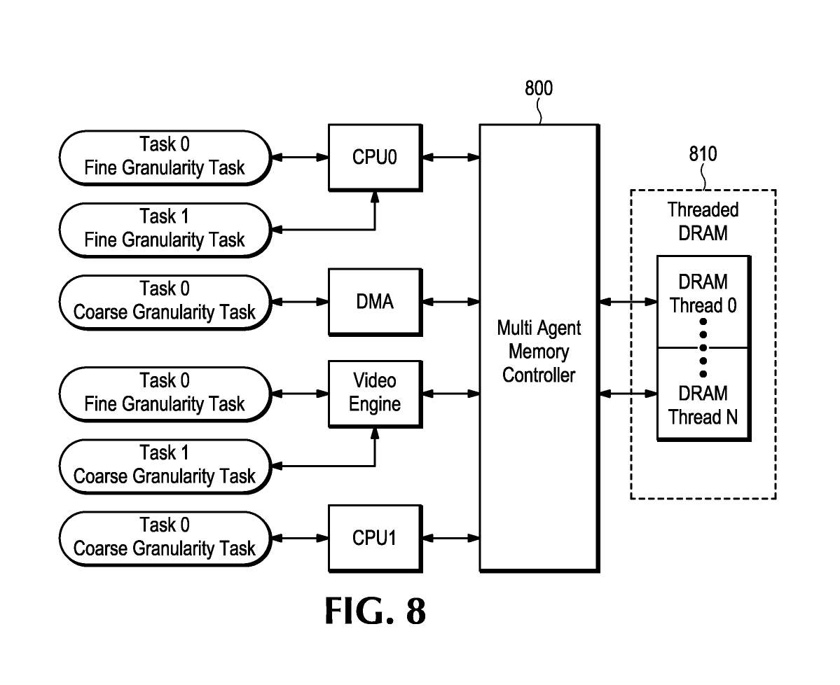

FIG. 8 is a simplified block diagram illustrating various “tasks” of both fine and coarse granularity, all presented to a multi-agent memory controller 800 for accessing a multi-channel memory or threaded DRAM 810. For illustration, fine granularity tasks 0 and 1 are executed on CPU-0 and a fine granularity task 0 executes on a video engine. Coarse granularity tasks are shown in the drawing as well, for example, coarse granularity task 0 running on CPU-1. Thus, the memory controller 800 is faced with various demands for memory access. Next we present timing diagrams that illustrate such scheduling challenges, and illustrate dynamic scheduling strategies to provide improved performance in connection with such requests, taking advantage of multi-threaded or multi-channel memory. Following the timing diagrams we will describe a preferred architecture for a memory controller capable of implementing scheduling strategies of the types shown.

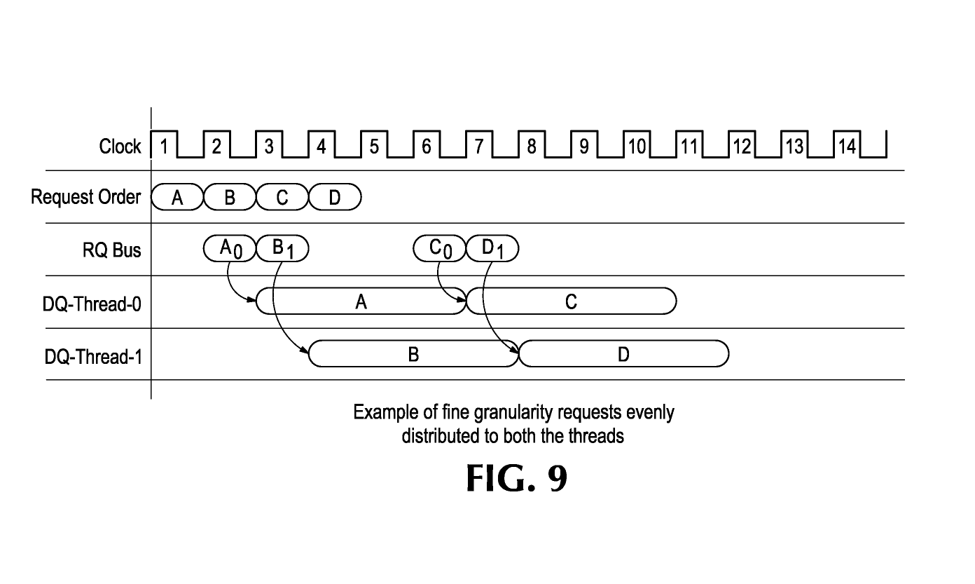

FIG. 9 is a simplified timing diagram illustrating an example of fine granularity requests evenly distributed to both threads of a two-threaded memory. The number of threads is not limiting, this example is merely illustrative. The requests, labeled A, B, C, and D are all fine granularity requests, received at the controller in the order shown (synchronized to the clock signal shown). As before, memory operation timing details are ignored for simplicity. Here, request A0 is directed to Thread-0 and request B1 is to Thread-1. Rank/chip selects may be used as the thread selector.

FIG. 10 is a simplified timing diagram illustrating an example of fine and coarse granularity requests distributed to two memory threads according to an exemplary unbalanced loading. Hatching is used in the drawing to distinguish fine granularity requests (A, B, G) from coarse granularity requests (C, D, E, F), as indicated in the key at the lower right The requesting agent may specify, in at least some embodiments, the size of the request. In this illustration, fine granularity requests A and B are directed to threads 0 and 1, respectively (DQ-Thread-0 and DQ-Thread-1) as before. The next request on the RQ bus, coarse granularity request C, is directed to Thread 0 following request A. A first access burst C1 proceeds, followed by C2, continuing to utilize Thread 0 where the C request data resides. After request C completes, request D follows, again on Thread 0, etc. As can be seen from FIG. 10, back-to-back coarse data requests to the same thread may result in significant extra latency for subsequent request(s), while a different thread may at the same time remain underutilized.

Referring now to DQ-Thread-1 in the diagram, fine granularity request B is scheduled on this thread. Request G is eventually directed to this Thread-1, but there is a performance “hole” on Thread-1 DQ bus as shown, because prior to the controller receiving request G there were no queued requests for Thread 1 (although several requests were queued for Thread 0).

FIG. 11 is a simplified timing diagram illustrating an example of dynamic scheduling of different portions of a coarse granularity request simultaneously on two memory threads, where the address range accessed by request C is striped across the two threads. In this illustration, requests A, B and D are fine granularity requests, while C is a coarse granularity request, requiring two access bursts C1 and C2. The fine granularity requests A and B are directed to threads 0 and 1, respectively (DQ-Thread-0 and DQ-Thread-1) as before. Next, C1 is directed to Thread 0 and C2 is directed to Thread 1. The two access bursts can proceed simultaneously in an embodiment by supplying a common command and address while enabling chip selects on both threads, or if the two threads have separate command/address buses, placing a similar command on both buses (there could be, as illustrated and depending on prior traffic, a small penalty in this case while waiting for both treads to become available to enable the simultaneous access operations.) This scheduling improves performance and reduces latency as can be seen in the diagram. This striping mechanism can be used for both writes and reads. A fine granularity request to a striped address region can also be made, with the memory controller determining which thread contains a particular data element.

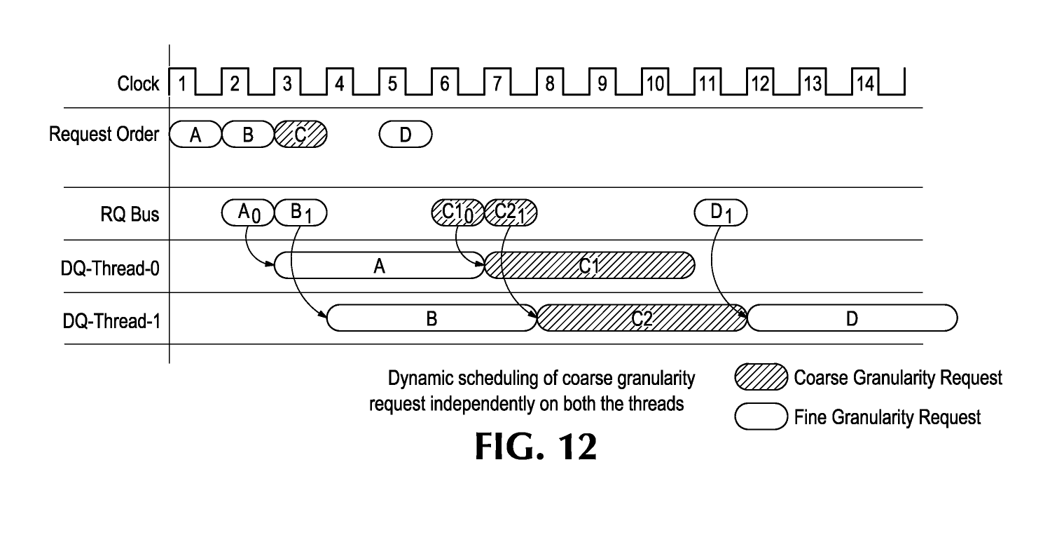

The timing diagram of FIG. 12 shows an example of dynamic scheduling of a coarse granularity request as two subrequests, potentially independently, on two memory threads. Coarse granularity request C is distributed, with a first subrequest C1 distributed to Thread-0 following request A, and a second subrequest C2 distributed to Thread-1 following request B. Again, dynamic scheduling is applied to minimize waiting and thus improve performance. In FIG. 12, for a data write, the data is striped onto the two threads as their respective channels become available. For a data read, FIG. 12 can illustrate either a striped read or reads to two instances of the same data address range on separate threads.

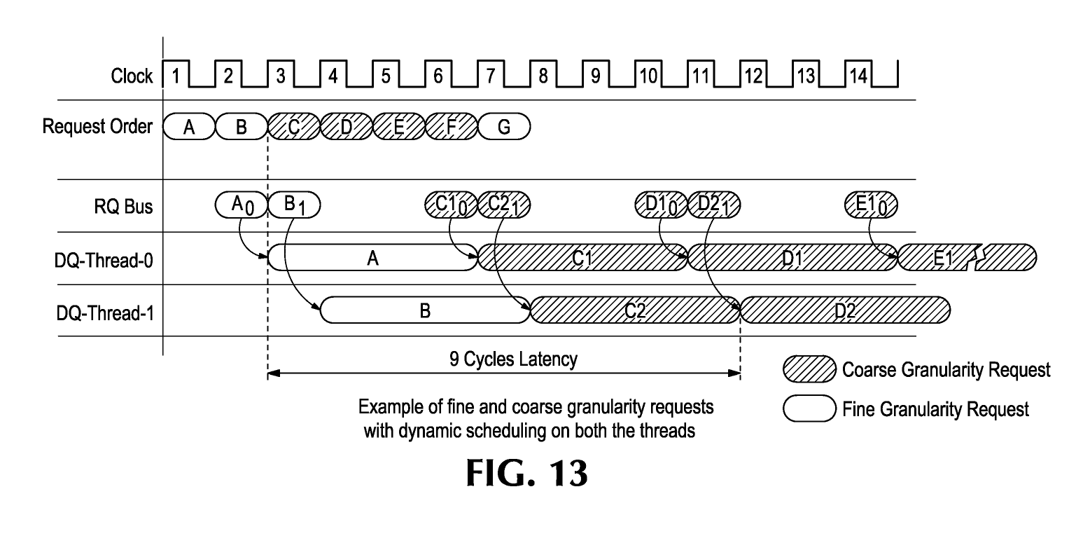

FIG. 13 illustrates performance gains achieved through dynamic scheduling on both memory threads, for the memory transaction request order illustrated in FIG. 10. This diagram shows a mix of fine and coarse granularity requests as before. Fine granularity requests A and B proceed as before. Coarse granularity request C is directed to a memory address range that is striped across both threads. Accordingly, the memory controller creates two subrequests, C1 and C2, with subrequest C1 directed to Thread-0, and subrequest C2 directed to Thread-1. Coarse granularity requests D, E, F can likewise take advantage of both threads, thereby removing sensitivity to request ordering. Thus coarse granularity requests can be split across the memory threads if this improves scheduling and/or reduces latency. With this dynamic scheduling on both threads (or N threads if there be more available), performance is improved and latency reduced.

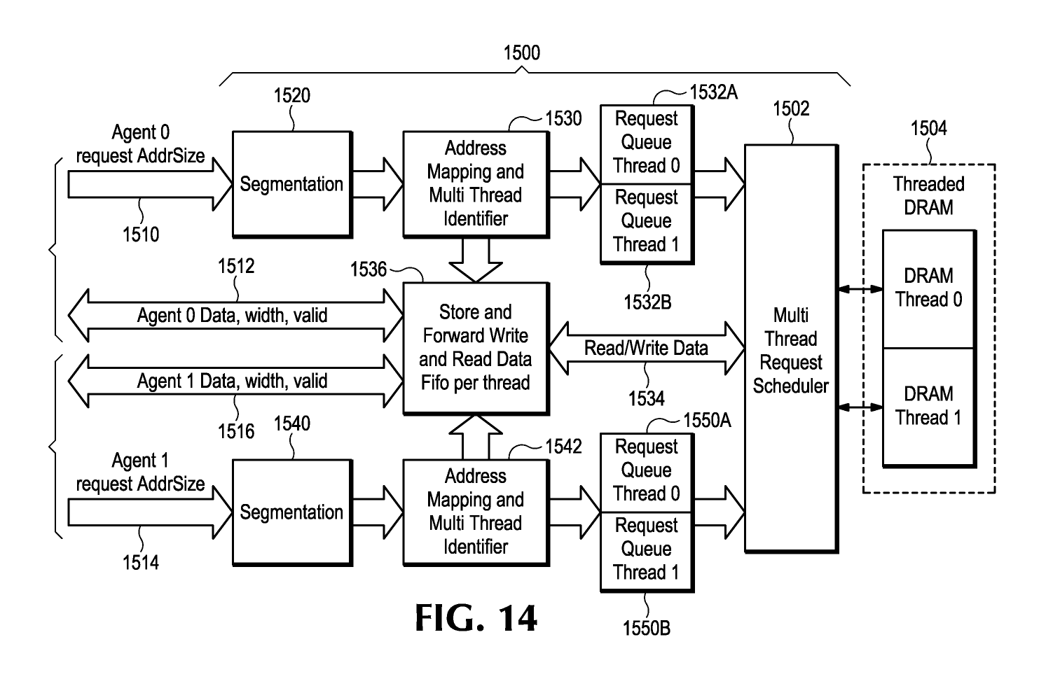

FIG. 14 is a simplified block diagram illustrating one example of a memory controller architecture to implement dynamic scheduling of memory access requests as described above. In the figure, a controller 1500 includes a multi-thread request scheduler 1502 coupled for access to a threaded memory 1504. Two threads are shown in the memory, Thread 0 and Thread 1, although there may be more. The scheduler 1502 generates all command, address, select and other control signals as required for accessing the memory 1504.

At the left side of the drawing, a first interface is coupled for communications with Agent 0. The interface may comprise a request part 1510 and a data part 1512 (alternately, requests/responses can be packetized with address, command, and/or data portions sharing common lines of a bus). Similarly, a second interface arranged for communications with Agent 1 may comprise a request part 1514 and a data part 1516 (alternately, multiple agents can share a common interface). The first interface request is coupled to a segmentation circuit 1520, and thence to address mapping logic 1530. Logic 1530 also implements a multi-thread identifier, to determine whether or not multiple threads of the memory should be accessed to service the current request. This logic determines a granularity or size of the request. As illustrated above, a coarse granularity request may be advantageously split across multiple threads of the memory, when the data has been configured across multiple threads. A coarse granularity request may be defined as one where the data size of the request is greater than the single-transaction data size of one channel or thread.

In FIG. 14, there are two memory threads, and the logic 1530 may write requests to either or both of the request queues 1532A and 15328 as appropriate. In this way, the request may be scheduled to either or both threads of the memory as discussed above. The first interface data portion 1512, associated with Agent 0 data, is coupled to a store and forward buffer 1536. This buffer may be implemented to provide write and read data FIFO buffers per thread, to store and forward data in both directions. The buffer 1536 is coupled to the request scheduler 1502 to transfer read and write data via a path 1534. The data path may have a width, for example, equal to the data path DQ size of each thread of memory 1504.

In operation, for example in the case of a coarse granularity write request from Agent 0 at interface 1510, the logic 1530 may generate two fine requests for both threads, Thread 0 and Thread 1, and enter them into the respective request queues, 1532A, 15328, for processing by the scheduler 1502, to stripe the data across both threads. Alternately, the logic 1530 may generate duplicate requests to both threads, where the data is to be cloned to both threads. The write data, on interface 1512, will be buffered (stored and forwarded to the scheduler) by the buffer 1536, under control of the multi-thread identifier in logic 1530, so it reaches the appropriate threads of memory as scheduled.

The second user request interface 1514, introduced above, is also coupled to a corresponding segmentation circuit 1540, and thence to address mapping and multi-thread identifier 1542 for servicing that user (Agent 1). The buffer 1542 is coupled to corresponding request queues, per thread, 1550A and 15508 as shown. These request queues also are coupled to the scheduler 1502 for accessing either or both threads of the memory 1504, as discussed above with regard to the Agent 0 interface. The buffers 1536 can effectively switch or steer data between the memory data paths via 1534 and various user or agent interfaces. Only two user interfaces are shown here, but this illustration is not limiting. For example, FIG. 1 shows several different applications and agents coupled to a memory controller, as does FIG. 8.

It will be obvious to those having skill in the art that many changes may be made to the details of the above-described embodiments without departing from the underlying principles of the invention. The scope of the present invention should, therefore, be determined only by the following claims.

1. A method of operating a memory controller comprising:
receiving a first memory access read request from an agent;
determining that at least a portion of data requested by the read request is accessible through a first channel of a multi-channel memory, and at least a portion of data requested by the read request is accessible through a second channel of the multi-channel memory; and
scheduling at least one memory access operation responsive to the memory access read request, wherein the scheduling of the at least one memory access operation depends on the availability of both the first and second channels.

2. The method of claim 1, wherein the read request is a coarse-grained request, and wherein scheduling at least one memory access operation responsive to the read request comprises scheduling at least one fine-grained memory access operation on the first channel and scheduling at least one fine-grained memory access operation on the second channel.

3. The method of claim 2, wherein all of the data requested by the read request is accessible through both the first and second channels of the multi-channel memory.

4. The method of claim 2, wherein the respective portions of the data requested by the read request accessible through the first and second channels are mutually exclusive.

5. The method of claim 1, wherein all of the data requested by the read request is accessible through both the first and second channels of the multi-channel memory, and wherein scheduling at least one memory access operation responsive to the memory access read request comprising selecting one of the first and second channels to schedule the at least one memory access operation so as to minimize latency for the read request.

6. The method of claim 1, further comprising:
receiving a second memory access read request from an agent;
determining that the data requested by the second read request is accessible only through one of the first and second channels; and
scheduling at least one second memory access operation responsive to the second memory access read request, wherein the scheduling of the at least one second memory access operation depends only on availability of the channel through which the data requested by the second read request is accessible.

7. The method of claim 2 and further comprising executing the fine-grained memory access operation on the first channel, and executing the fine-grained memory access operation on the second channel, concurrently.

8. The method of claim 2 and further comprising executing the fine-grained memory access operation on the first channel, and executing the fine-grained memory access operation on the second channel, substantially simultaneously.

9. The method of claim 2 and further comprising executing the fine-grained memory access operation on the first channel, and executing the fine-grained memory access operation on the second channel, independently.

10. The method of claim 1 wherein the multi-channel memory comprises DRAM.

11. The method of claim 1 wherein the multi-channel memory comprises module threaded memory, each thread of the memory corresponding to a channel of the multi-channel memory.

12. The method of claim 1 wherein the multi-channel memory is configured to store duplicate data in respective clone memory ranges accessible respectively through the first and second channels.

13. The method of claim 12, wherein determining that at least a portion of the data requested is accessible through the first channel and at least a portion of the data requested is accessible through the second channel comprises detecting that the first memory access request is directed to the clone memory ranges.

14. A memory controller comprising:
a client interface for receiving a memory access read request from a client;
a multi-channel memory interface for interacting with a multiple-channel memory;
logic for determining that at least a portion of data requested by the read request is accessible through a first channel of the multi-channel memory, and at least a portion of data requested by the read request is accessible through a second channel of the multi-channel memory; and
a scheduler arranged to schedule at least one memory access operation responsive to the memory access read request, wherein the scheduling of the at least one memory access operation depends on availability of both the first and second channels.

15. The memory controller of claim 14, including logic for determining that a received memory access read request is a coarse-grained request, and wherein the scheduler is arranged to schedule at least one fine-grained memory access operation on the first channel and at least one fine-grained memory access operation on the second channel in response to the coarse-grained read request.

16. The memory controller of claim 15, including logic for determining whether all of the data requested by the read request is accessible through both the first and second channels of the multi-channel memory.

17. The memory controller of claim 15, including logic for determining what portion of the data requested by the read request is accessible through the first channel and what portion of the requested by the read request is accessible through the second channel.

18. The memory controller of claim 14, including logic for determining that all of the data requested by the read request is accessible through both the first and second channels of the multi-channel memory, and wherein the controller is arranged to select one of the first and second channels on which to schedule the at least one memory access operation so as to minimize latency for the read request.

19. The memory controller of claim 14, further including request logic for assessing a granularity of the request, and wherein the scheduler is arranged, responsive to a case where the granularity of the request is assessed to be greater than the memory access granularity, to split the request across at least two of the multiple different channels of the multi-channel memory.

20. The memory controller of claim 14, further including request logic for assessing a granularity of the request, and wherein the scheduler is arranged, responsive to a case where the granularity of the request is assessed to be greater than the memory access granularity of one channel, to split the request across at least two of the multiple different channels of the multi-channel memory.
